(19) United States
(12) Patent Application Publication
(10) Pub. No.: US 2014/0210520 A1
(43) Pub. Date: Jul. 31, 2014

(54) LOW POWER LOW VOLTAGE DIFFERENTIAL DRIVER

(71) Applicant: RAYTHEON COMPANY, Waltham, MA (US)

(72) Inventor: MICKY HARRIS, LOMPOC, CA (US)

(73) Assignee: RAYTHEON COMPANY, WALTHAM, MA (US)

(21) Appl. No.: 13/753,470

(22) Filed: Jan. 29, 2013

(51) Int. Cl. H03K 3/01

(52) U.S. Cl. CPC H03K 3/01
USPC 327/108

(57) ABSTRACT

The present invention provides for a differential driver for transmitting a differential signal including: a first power source to supply a first voltage; a second power source to supply a second voltage that is less than the first voltage; a current steering circuit coupled between the first power source and the second power source, the current steering circuit for steering a current into either a positive differential output node or a negative differential output node to transmit the differential signal according to a data signal and a dataN signal; a resistor interposed between the first power source and the current steering circuit; and a constant current sink interposed between the current steering circuit and the second power source, the constant current sink for sinking the current having a substantially constant value, in which, the dataN signal is the inverse of the data signal.

### BACKGROUND

1. Field

Aspects of the present invention relate generally to data signaling devices, and more particularly, to a low power low voltage differential driver.

2. Description of Related Art

Increasingly, electronic devices require high speed data communication, either internally or with external devices. Low voltage differential signaling (LVDS) is one type of communication technology that may be used to implement the high speed data communication requirement for these electronic devices. LVDS is a way to communicate data at a high speed using a low voltage swing differentially over two signal lines.

A LVDS communication circuit may include a differential driver (i.e., a transmitter) connected to a terminated receiver through a pair of transmission lines. The differential driver receives a logic level data signal and outputs an analog differential signal. The analog differential signal is transmitted via the pair of transmission lines to the terminated receiver. The terminated receiver receives the analog differential signal and outputs a logic level data signal.

The differential driver has two output terminals. A corresponding one of the pair of transmission lines is connected to each of the two output terminals. These output terminals alternate between sourcing and sinking a (substantially) constant current (e.g., a 4 mA current). Thus, the direction of the current flowing through the pair of transmission lines also alternates. The direction of the current corresponds to the logic level transmitted (e.g., a 0 or 1).

The terminated receiver includes a terminating resistor (e.g., a 100Ω resistor) and a differential receiver. The differential receiver is a high impedance device that detects a voltage difference between two inputs. The terminating resistor is coupled between the two inputs. A corresponding one of the pair of transmission lines is connected to each of the two input terminals. Accordingly, current flows from one of the output terminals of the differential driver, through the terminating resistor, to the other output terminal of the differential driver. According to Ohm's law, the current flowing through the terminating resistor results in a voltage difference between the two input terminals of the differential receiver. This is the differential voltage of the differential signal. By changing the direction of the current, the polarity of this differential voltage changes in turn. The differential receiver senses this polarity change to determine the logic level of the differential signal.

A low voltage differential signal produced by a low voltage differential driver has a low peak-to-peak amplitude (e.g., from about 250 mV to about 450 mV). For example, in a LVDS communication circuit having a drive current of 4 mA and a termination voltage of 100Ω, the differential voltage is 400 mV. This low voltage swing helps to reduce power dissipation, while maintaining high transmission speeds (e.g., 1 Gb/s).

The differential signal in LVDS includes a common mode voltage (e.g., a common mode voltage of about 1.2 V). The common mode voltage is the average of the voltages on the pair of transmission lines. By offsetting the differential signal by the common mode voltage, the receiver may be unaffected (or less affected) by variations in the differential signal. In one embodiment, the receiver may accept an input range of 0 V to 2.4 V, the common mode voltage may be about 1.2 V, and the common mode input range may be about ±1 V.

To set the common mode voltage, a differential driver may include a common mode feedback circuit. The common mode feedback circuit may be configured to sense the common mode voltage, compare the sensed common mode voltage with a desired voltage, and adjust the common mode voltage. The common mode feedback circuit may include a plurality of circuit components, e.g., a plurality of transistors and resistors. For example, the common mode feedback circuit may include sense resistors in parallel with the terminated receiver to sense the common mode voltage. Each of the components of the common mode feedback circuit not only takes up valuable space, but also consumes energy. In certain applications, the common mode feedback circuit consumes about 30% more power than otherwise required to provide the differential signal.

Frequently, design considerations, such as, package size, portability, or cost, drive demand for improving energy efficiency of and/or reducing the number of components in the electronic devices that require high speed data communication. By improving the efficiency of the communications circuits used in these electronic devices, the overall energy efficiency may be improved. Similarly, by reducing the number of components in the communication circuits, the overall number of components may be reduced. Accordingly, aspects of embodiments of the present invention are directed toward improving the energy efficiency of and/or reducing the number of components in LVDS communication circuits.

### SUMMARY

Aspects of the present invention are directed toward providing a low voltage differential signaling (LVDS) driver having low power consumption and/or a low number of components. Thus, for example, embodiments of the present invention provide LVDS drivers having an improved common mode setting circuit.

An embodiment of the present invention provides for a differential driver for transmitting a differential signal including: a first power source to supply a first voltage; a second power source to supply a second voltage that is less than the first voltage; a current steering circuit coupled between the first power source and the second power source, the current steering circuit for steering a current into either a positive differential output node or a negative differential output node to transmit the differential signal according to a data signal and a dataN signal; a resistor interposed between the first power source and the current steering circuit; and a constant current sink interposed between the current steering circuit and the second power source, the constant current sink for sinking the current having a substantially constant value, in which, the dataN signal is the inverse of the data signal.

In an embodiment, the current steering circuit receives the current having a voltage that is less than the first voltage by a voltage drop across the resistor.

The current steering circuit may be a bridged switch driver. The current steering circuit may steer the current to flow from the positive differential output node through a terminating resistor to the negative differential output node when the data signal is high, and the current steering circuit may steer the current to flow from the negative differential output node through the terminating resistor to the positive differential output node when the data signal is low.

In an embodiment, the current steering circuit includes: a current input node coupled to the first power source through the resistor; a current output node coupled to the constant current sink; a first switch coupled between the current input node and the negative differential output node; a second switch coupled between the negative differential output node and the current output node; a third switch coupled between the current input node and the positive differential output node; and a fourth switch coupled between the current input node and the positive differential output node. The first switch and the third switch may include p-type transistors, and the second switch and the fourth switch may include n-type transistors.

The first switch and the fourth switch may turn on when the data signal is low, and the second switch and the third switch may turn on when the data signal is high.

In an embodiment, the first switch has: an input terminal coupled to the current input node; an output terminal coupled to the negative differential output node; and a gate for receiving the data signal, the second switch has: an input terminal coupled to the negative differential output node; an output terminal coupled to the current output node; and a gate for receiving the data signal, the third switch has: an input terminal coupled to the current input node; an output terminal coupled to the positive differential output node; and a gate for receiving the dataN signal, and the fourth switch has: an input terminal coupled to the positive differential output node; an output terminal coupled to the current output node; and a gate for receiving the dataN signal.

In an embodiment, the current steering circuit further includes a back termination circuit. The back termination circuit may include a capacitor coupled between the current input node and the current output node.

The current steering circuit may further include an AC glitch suppressor, which may include: a fifth switch interposed between the negative differential output node and the second switch, the fifth switch having: an input terminal coupled to the negative differential output node; an output terminal coupled to the input terminal; and a gate for receiving the dataN signal; a sixth switch interposed between the fifth switch and the second switch, the sixth switch having: an input terminal coupled to the output terminal of the fifth switch; an output terminal coupled to the input terminal and coupled to an input terminal of the second switch; and a gate for receiving the dataN signal; and a seventh switch interposed between the positive differential output node and the fourth switch, the seventh switch having: an input terminal coupled to the positive differential output node; an output terminal coupled to the input terminal; and a gate for receiving the data signal; and an eighth switch interposed between the seventh switch and the fourth switch, the eighth switch having: an input terminal coupled to the output terminal of the seventh switch; an output terminal coupled to the input terminal and coupled to an input terminal of the fourth switch; and a gate for receiving the data signal, in which the second switch, the third switch, the fifth switch, and the eighth switch turn on when the data signal is high, and in which the first switch, the fourth switch, the sixth, and the seventh switch turn on when the data signal is low.

Additionally, another embodiment of the present invention provides for a differential communication circuit including: a differential receiver including: a positive input terminal; a negative input terminal; a positive transmission line coupled to the positive input terminal of the differential receiver; a negative transmission line coupled to the negative input terminal of the differential receiver; a terminating resistor coupled between the positive transmission line and the negative transmission line; and a differential transmitter including: a first power source for supplying a first voltage; a second power source for supplying a second voltage that is less than the first voltage; a current steering circuit coupled between the first power source and the second power source, the current steering circuit being for steering a current into either a positive differential output node or a negative differential output node to transmit a differential signal according to a data signal and a dataN signal; a resistor interposed between the first power source and the current steering circuit; and a constant current sink interposed between the current steering circuit and the second power source, the constant current sink for sinking the current having a substantially constant value, in which the dataN signal is the inverse of the data signal, the positive differential output node is coupled to the positive transmission line, and the negative differential output node is coupled to the negative transmission line.

The current steering circuit may receive the current having a voltage less than the first voltage by a voltage drop across the resistor.

The current steering circuit may include a bridged switch driver. In an embodiment, the current steering circuit steers the current to flow from the positive differential output node through the terminating resistor to the negative differential output node when the data signal is high, and the current steering circuit steers the current to flow from the negative differential output node through the terminating resistor to the positive differential output node when the data signal is low.

The current steering circuit may include: a current input node coupled to the first power source through the resistor; a current output node coupled to the constant current sink; a first switch coupled between the current input node and the negative differential output node; a second switch coupled between the negative differential output node and the current output node; a third switch coupled between the current input node and the positive differential output node; and a fourth switch coupled between the current input node and the positive differential output node.

Further, another embodiment of the present invention provides a method of driving a differential signal, the method including: providing a constant current at a first voltage; shifting the first voltage to a second voltage; and selectively steering the constant current at the second voltage to flow either from a positive differential node, through a terminating resistor, to a negative differential node, or from the negative differential node through the terminating resistor, to the positive differential node, according to a data signal to transmit the differential signal.

Shifting the first voltage to the second voltage may include supplying the constant current at the first voltage to an offsetting resistor before selectively steering the constant current.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 is schematic diagram of a low power LVDS communication circuit according to an embodiment of the present invention.

FIG. 2 is a schematic diagram of a differential driver of FIG. 1.

FIG. 3 is a timing diagram illustrating an operation of the LVDS communication circuit according to the embodiment of the present invention illustrated in FIG. 2.

FIG. 4 is a schematic diagram of a differential driver having a back termination circuit according to an embodiment of the present invention.

FIG. 5 is a schematic diagram of a differential driver having an AC glitch suppressor circuit according to another embodiment of the present invention.

### DETAILED DESCRIPTION

Aspects of embodiments of the present invention provide for a low voltage differential signaling (LVDS) communication circuit including a differential driver having an improved common mode setting circuit.

For example, a differential driver according to an embodiment of the present invention includes an offsetting impedance as part of the common mode setting circuit. The offsetting impedance is interposed between a voltage source and each of a current steering circuit and a current sink. This offsetting impedance may be included in a differential driver instead of a common mode feedback circuit, and may be an offsetting resistor (e.g., a 50Ω resistor). By including the offsetting impedance according to the embodiment of the present invention instead of a common mode feedback circuit in a differential driver, energy efficiency may be increased and the number of components may be reduced.

A low power, low voltage differential signaling (LVDS) communication network according to exemplary embodiments of the present invention will now be described in more detail with reference to the accompanying drawings so that a person having ordinary skill in the art may readily make and use embodiments of the present invention.

In the following detailed description, only certain embodiments of the present invention are shown and described, by way of illustration. As those skilled in the art would recognize, the invention may be embodied in many different forms and should not be construed as being limited to the embodiments set forth herein. Instead, the detailed description should be construed to encompass the scope of the appended claims and equivalents thereof. Also, in the present application, when an element is referred to as being “coupled” (e.g., electrically coupled or connected) to another element, it can be directly coupled to the another element or indirectly coupled to the another element with one or more intervening elements interposed therebetween. Hereinafter, like reference numerals refer to like elements.

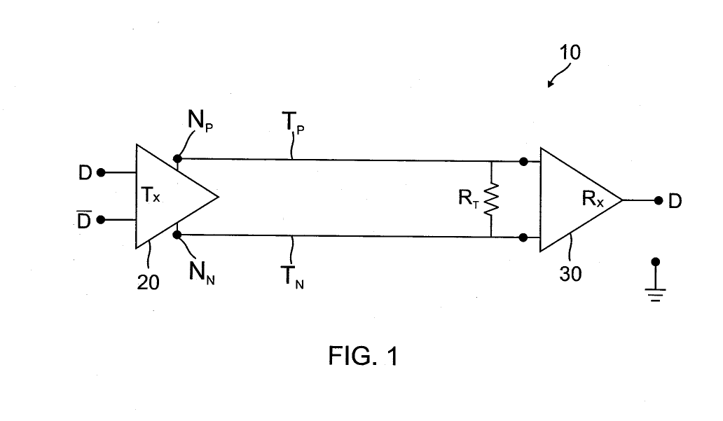

FIG. 1 is schematic diagram of a low power LVDS communication network according to an embodiment of the present invention.

A low power LVDS communication network 10 includes a differential driver 20 (i.e., a transmitter) coupled to a differential receiver 30 through a transmission line pair (Tp and Tn), with a terminating resistor Rt coupled between the transmission line pair (Tp and Tn) at the differential receiver 30. The transmission line pair includes a positive transmission line Tp and a negative transmission line Tn.

The transmission line pair may be implemented with a twisted pair cable, PCB traces, or the like. The impedance of the terminating resistor Rt may be matched to the differential impedance of the transmission line pair (Tp and Tn) to inhibit reflections. For example, the differential impedance of the transmission line pair (Tp and Tn) and the impedance of the terminating resistor Rt may be 100Ω. The terminating resistor Rt completes a current path of the transmission line pair (Tp and Tn), and is placed close to the input of the differential receiver 30.

The differential driver 20 is configured to selectively provide a (substantially) constant current I in a first or second direction (according to input data) to transmit a differential signal to the differential receiver 30. The differential driver 20 receives the input data from a data line D and an inverse data line D̅. The direction of the current I corresponds to the logic level to be transmitted. That is, when transmitting a 1, the constant current I may be steered in the first direction, and when transmitting a 0, the constant current I may be steered in the second direction.

Accordingly, the constant current I flows through the transmission line pair (Tp and Tn) to the terminating resistor Rt in either the first or second direction. Because the terminating resistor Rt is coupled between the transmission line pair (Tp and Tn), the direction of the current I through the terminating resistor Rt also flows in either the first or second direction. According to Ohm's law, when current flows through a resistor, a corresponding voltage drop, which is the product of the current and the resistance, occurs across the resistor. Here, this voltage drop corresponds to the differential voltage of the differential signal. Because the direction of the current alternates, the polarity of the differential voltage alternates as well. This is the differential signal observed by the differential receiver.

According to the LVDS standard, the differential signal may have a peak-to-peak voltage within a range of about 250 mV to about 450 mV. In the circuit described above, the peak-to-peak voltage corresponds to the voltage drop across the terminating resistor Rt. Accordingly, the peak-to-peak voltage should correspond to Rt×I. For example, according to an embodiment of the present invention, Rt may be 100Ω and I may be 4 mA. Here, the peak-to-peak voltage of the differential signal is 400 mV.

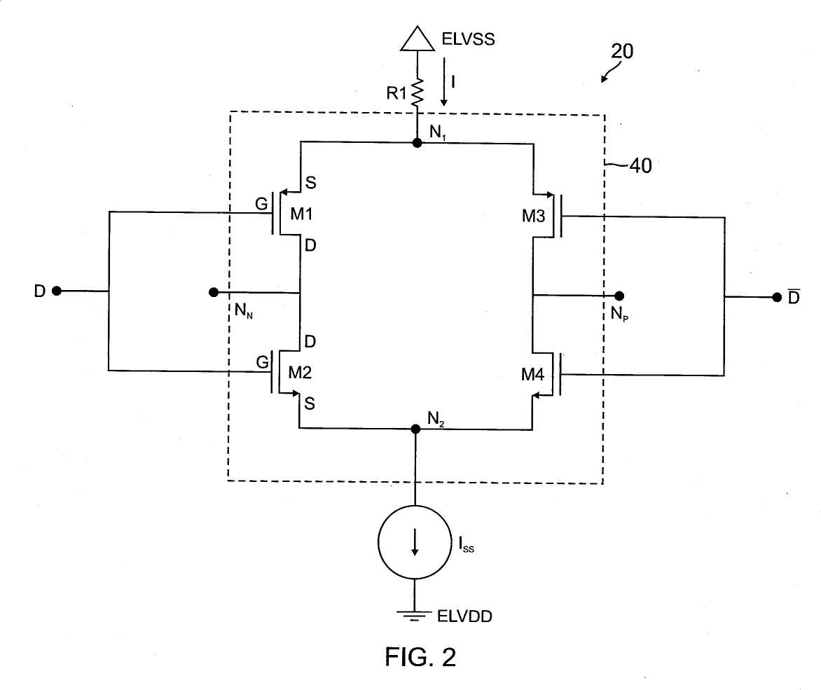

The LVDS standard also describes the differential signal as having a common mode voltage. The common mode voltage is the average of the voltages on the transmission line pair (Tp and Td), and may be, for example, about 1.2 V. The differential driver sets the common mode voltage. The circuit for setting the common mode voltage is discussed in greater detail in connection with FIG. 2. By including the common mode voltage in the differential signal, the differential receiver 30 may better reject common mode noise injected into the differential signal. For example, if the differential receiver 30 accepts an input range of 0 V to 2.4 V and the common mode voltage is 1.2 V, the common mode noise rejection may be about ±1 V.

The differential receiver 30 is a high impedance device that detects a voltage difference between two inputs. As described above, the differential receiver 30 is configured to measure the voltage drop across the terminating resistor Rt. That is, the differential receiver 30 measures the differential signal voltage. The differential receiver 30 then determines the transmitted logic level according to the measured differential signal voltage. In particular, the differential receiver 30 may determine the logic level of the signal according to the polarity of the measured voltage. The differential receiver 30 outputs the determined logic level as output data to an output data line D′.

Therefore, in the low power LVDS communication circuit 10: the differential driver 10 receives the input data, generates the differential signal according to the input data, and outputs the differential signal to the transmission line pair (Tp and Td) to the terminated differential receiver 30; and the differential receiver 30 senses the differential signal as the polarity of the voltage across the terminating resistor Rt, and generates the output data corresponding to differential signal.

Hereinafter, the differential driver 20 having an improved common mode setting circuit according to an embodiment of the present invention is described in detail with reference to FIG. 2. FIG. 2 is a schematic diagram of the differential driver of FIG. 1.

As described above, the differential driver 20 generates the differential signal corresponding to the input data and transmits the differential signal to the terminated receiver. The differential driver 20 according to the present invention sets the common mode voltage without the need for a common mode feedback circuit, thereby providing a differential driver with improved efficiency and fewer components.

As shown in FIG. 2, the differential driver 20 includes a first power supply ELVSS, a second power supply ELVDD, a constant current sink Iss, an offsetting resistor R1, and a current steering circuit 40.

The first power supply ELVSS provides a first voltage, and the second power supply ELVDD provides a second voltage that is less than the first voltage. For example, according to an embodiment of the present invention, the first voltage may be about 1.8 V and the second voltage may be about 0 V.

The constant current sink Iss may be interposed in-between the first power supply ELVSS and the second power supply ELVDD. The constant current sink Iss is configured to sink a constant current I. That is, the constant current sink Iss is provided to maintain the constant current I at a set level (e.g., a predetermined level). For example, according to an embodiment of the present invention, the constant current sink Iss may be configured to maintain the constant current I at about 4 mA. The constant current I flows from the first power supply ELVSS to the second power supply ELVDD via the offsetting resistor R1, the current steering circuit 40, and the constant current sink Iss.

The current steering circuit 40 is configured to selectively steer the constant current I in the first or second direction according to the input data. The input data represents the information to be transmitted via the LVDS communication network 10. The input data is provided by an external device, for example, an external digital signal processor (DSP), to the current steering circuit via the data line D and the inverse data line D̅. The input data includes a data signal and an inverse data signal, which is the inverse of the data signal. The data signal and the inverse data signal are logic level signals, i.e., 1s and 0s. Therefore, when the data signal is 1, the inverse data signal is 0. The data signal is provided via the data line D, and the inverse data signal is provided via the inverse data line D̅.

The current steering circuit 40 selects the direction that the constant current I flows depending on the logic level of the input data. For example, when the data signal is 1 (the inverse data signal is 0), the current steering circuit 40 may steer the constant current I in the first direction, and when the data signal is 0 (the inverse data signal is 1), the current steering circuit 40 may steer the constant current I in the second direction. As described above, by alternating the direction that the constant current I flows, the polarity of the voltage across the terminating resistor Rt alternates in turn. The differential receiver 30 then determines the logic level of the transmitted signal according to the polarity of the measured voltage, and outputs the determined logic level as the output data signal to the output data line D′.

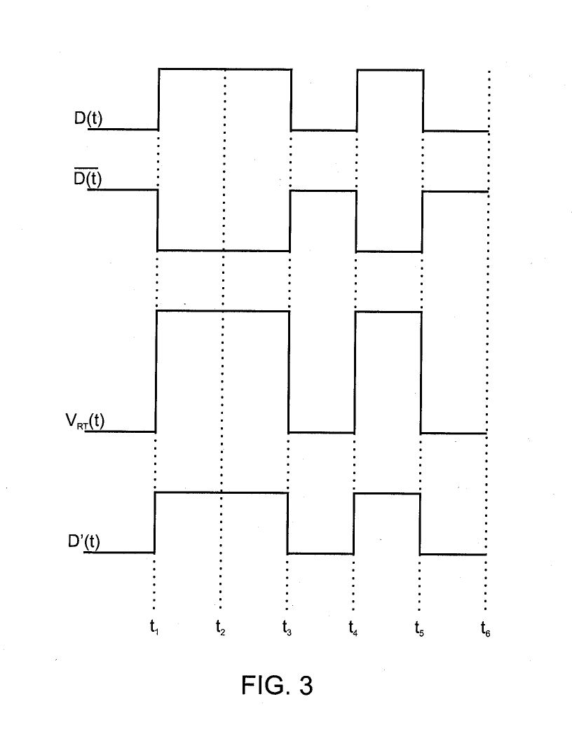

Referring now to FIG. 3, FIG. 3 is a timing diagram illustrating an operation of the LVDS communication circuit according to the embodiment of the present invention illustrated in FIG. 2. FIG. 3 illustrates the relationship between the data signal on the data line D, the inverse data signal on the inverse data line D̅, the differential signal as sensed by the differential receiver 30 (i.e., the voltage across the terminating resistor Rt), and the output data signal on the output data line D′ as described above. Specifically, FIG. 3 illustrates that when the data signal is 0 (the inverse data signal is 1), the polarity of the voltage across the terminating resistor is negative, and the output data signal is 0, and when the data signal is 1 (the inverse data signal is 0), the polarity of the voltage across the terminating resistor is positive, and the output data signal is 1.

Referring back to FIG. 2, the current steering circuit 40 may be a bridged switch driver, e.g., an H-bridged switch driver, but is not necessarily limited thereto. The current steering circuit 40 illustrated in FIG. 2 is an example of an H-bridged switch driver, and is described in detail below.

The current steering circuit 40 is interposed between the offsetting resistor R1 and the constant current source Iss and is in the path of the constant current I from the first power source ELVSS to the second power source ELVDD. The current steering circuit 40 receives the constant current I from the first power source ELVSS at the current input node N1, and outputs the constant current I to the second power source ELVDD at the current output node N2.

Additionally, the current steering circuit 40 is coupled to the transmission line pair (Tp and Tn) to output the constant current I as the differential signal. The current steering circuit 40 is coupled to the positive transmission line Tp via the positive differential output node Np, and is coupled to the negative transmission line Tn via the negative differential output node Nn.

When the current steering circuit 40 selectively steers the constant current I in the first direction, the current may flow from the current input node N1, through the positive differential output node Np to the terminating resistor Rt via the positive transmission line Tp, to the negative differential output node Nn via the negative transmission line Tn, and to the current input node N1. The current steering circuit may select this current path when the data signal is 1 (inverse data signal is 0), which may result in the differential transmitter 30 outputting the output data as a 1.

When the current steering circuit 40 selectively steers the constant current I in the second direction, the current may flow from the current input node N1, through the negative differential output node Nn to the terminating resistor Rt via the negative transmission line Tn, to the positive differential output node Np via the negative transmission line Tn, and to the current input node N1. The current steering circuit may select this current path when the data signal is 0 (inverse data signal is 1), which may result in the differential transmitter 30 outputting the output data as a 0.

To steer the constant current I (i.e., to select the current path), the current steering circuit may include a first switch M1, a second switch M2, a third switch M2, and a fourth switch M4. According to an embodiment of the present invention, these switches may be arranged in an H-bridged switch configuration. These switches may be implemented with transistors, e.g., MOSFET transistors.

In FIG. 2, the first switch M1 is coupled between the current input node N1 and the negative differential output node Nn. The first switch M1 controls the flow of the constant current I from the current input node N1 to the negative differential input node Nn.

The second switch M2 is coupled between the current output node N2 and the negative differential output node Nn. The second switch M2 controls the flow of the constant current I from the negative differential output node Nn to the current output node N2.

The first switch M1 and the second switch M2 may form a first complementary pair of switches. That is, when the first switch M1 is controlled to be turned on, the second switch M2 is controlled to turn off. The first switch M1 and the second switch M2 may be controlled according to the data signal. Accordingly, the first switch M1 and the second switch M2 may be coupled to the data line D.

The third switch M3 is coupled between the current input node N1 and the positive differential output node Np. The third switch M3 controls the flow of the constant current I from the current input node N1 to the positive differential output node Np.

The fourth switch M4 is coupled between the current output node N2 and the positive differential output node Np. The fourth switch M4 controls the flow of the constant current I from the positive differential input node Np to the current output node N2.

The third switch M3 and the fourth switch M4 may form a second complementary pair of switches. That is, when the third switch M3 is controlled to be turned on, the fourth switch M4 is controlled to turn off. The third switch M3 and the fourth switch M4 may be controlled according to the inverse data signal. Accordingly, the third switch M3 and the fourth switch M4 may be coupled to the inverse data line D̅.

In the above arrangement, because the four switches are configured into two complementary pairs and controlled by complementary data signals, the current steering circuit 40 can selectively control the constant current I to flow in one of two paths (i.e., in the first or second direction). Specifically, when the data signal is a 1 (the inverse data signal is 0), the first transistor M1 and the fourth transistor M4 are off, and the second transistor M2 and the third transistor M4 are on. Accordingly, the constant current I flows in the first direction, which results in the differential receiver 30 determining and outputting a logic level of 1 at the output line D′. Conversely, when the data signal is a 0 (the inverse data is 1), the first transistor M1 and the fourth transistor M1 are on, and the second transistor M2 and the third transistor are off. Accordingly, the constant current I flows in the second direction, which results in the differential receiver 30 determining and outputting a logic level of 0 at the output line D′.

As mentioned above, the switches may be implemented with MOSFETs. In FIG. 2, the switches are shown as being implemented with NMOS and PMOS transistors. Here, the first switch M1 and the third switch M3 are PMOS transistors, and the second switch M2 and the fourth switch M4 are NMOS transistors. PMOS transistors are configured to turn on when the input signal is low, and NMOS transistors are configured to turn on when the input signal is high.

For the first transistor M1, a source is coupled to the current input node N1, a drain is coupled to the negative differential output node Nn, and a gate is coupled to the data line D. For the second transistor M2, a source is coupled to the current output node N2, a drain is coupled to the negative differential output node Nn, and a gate is coupled to the data line D. For the third transistor M3, a source is coupled to the current input node N1, a drain is coupled to the positive differential output node Np, and a gate is coupled to the inverse data line D̅ to receive the inverse data signal. And, for the fourth transistor M4, a source is coupled to the current output node N2, a drain is coupled to the positive differential output node Np, and a gate is coupled to the inverse data line D̅ to receive the inverse data signal.

As mentioned previously, the differential driver 20 controls the common mode voltage of the differential signal. The differential driver 20 according to aspects of the present invention includes an improved common mode voltage setting circuit having improved power efficiency and fewer parts as compared to a common mode voltage setting circuit including a common mode feedback circuit and sense resistors. In the differential driver 20 illustrated in FIG. 2, the common mode voltage is set, at least in part, by the offsetting resistor R1 and the constant current I.

The offsetting resistor R1 is coupled between the first power supply ELVSS and the current steering circuit 40 such that the constant current I flows through the offsetting resistor R1 before reaching the input current node N1. That is, the current path of the constant current I may be from the first power supply ELVSS, through the offsetting resistor R1, through one of the transmission line pair (Tp or Tn), through the terminating resistor Rt, through the other one of the transmission line pair (Tp or Tn), to ELVDD.

The common mode voltage Vcm is the average of the voltage at the two inputs (V1 and V2) of the differential receiver, i.e., Vcm=(V1+V2)/2. Because the difference between V1 and V2 is the voltage drop across the terminating resistor Rt, V2 can be expressed as V1−(I)(Rt). Accordingly, Vcm is: V1−(½)(I)(Rt). If the switch resistance is assumed to be zero, V1 can be expressed by: ELVSS−(I)(R1)−(I)(R_{L}), where R_{L} is the impedance of one of the lines of the transmission line pair (Tp or Tn). That is, Vcm=ELVSS−I(R1+R_{L}+0.5Rt).

In an embodiment of the present invention, ELVSS is 1.8 V, I is 4 mA, R1 is 50Ω, R_{L} is 50Ω, and Rt is 100Ω. Accordingly, Vcm=1.8−(0.004)(50+50+(0.5)(100))=1.2 V.

In embodiments of the present invention, the offsetting resistance Rt may be substantially equivalent to the impedance of one of the transmission line pairs to inhibit reflection at the differential driver.

Accordingly, aspects of embodiments of the present invention provide for a LVDS communication circuit including a differential driver having an improved common mode setting circuit, which comparatively reduces energy usage and the number of electronic components as compared to a common mode setting circuit including sensing resistors and a common mode feedback loop.

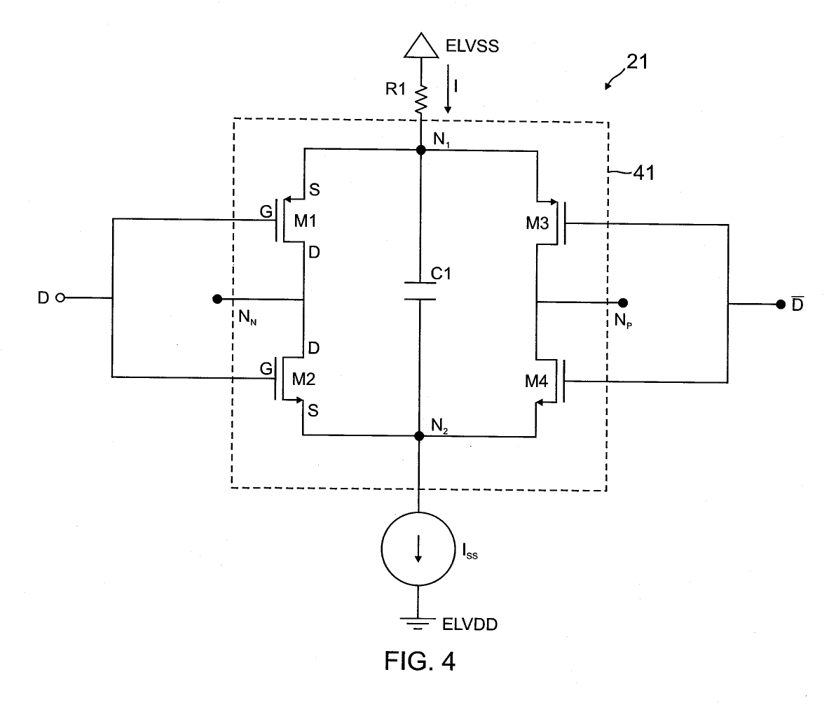

Referring now to FIG. 4, which is a schematic diagram of a low power LVDS driver having a back termination circuit according to another embodiment of the present invention. Since the low power LVDS driver according to the present embodiment may include substantially similar elements as those previously described, descriptions of certain aspects of the present embodiment are given by way of reference to the above descriptions and will not be described in detail herein.

Due to imperfect termination, package parasitics, component tolerances, or cross talk, there may be reflected waveforms returning to a differential driver. These reflected waveforms may adversely affect data transmission. This is particularly true when data rates are high (e.g., above 500 Mb/s). Accordingly, back termination (or source termination) may be provided at the driver end of the LVDS communication circuit to suppress reflections. The back termination may be provided by coupling back terminating resistors to the output of the differential driver (e.g., 200Ω termination, providing good enough match). However, this adds additional load to the output of the differential driver, and thereby increases power consumption of the differential driver.

Alternatively, back termination may be provided by the ON resistance Ron of switches of a current steering circuit, which are AC terminated with a capacitor. By providing the back termination with the resistance of the switches and the capacitor instead of back terminating resistors, power consumption of the differential driver may be reduced.

FIG. 4 illustrates a differential driver 21 according to another embodiment of the present invention. The differential driver 21 includes a first power source ELVSS, an offsetting resistor R1, a second power source ELVDD, a constant current sink Iss, and a current steering circuit 41.

The current steering circuit 41 is substantially similar to the current steering circuit 40 described above, except that it includes a capacitor C1. The capacitor C1 is coupled between a current input node N1 and a current output node N2. The capacitor C1 provides an AC termination component of the back termination.

The back termination also includes a resistive component. As described above, switches M1 through M4 switch in pairs to selectively steer a current through a positive differential output node Np and a negative differential output node Nn. Each of the switches M1 through M4 has an ON resistance Ron, and for each selected path of the current, two of the switches are concurrently on (e.g., M1 & M4; or M2 and M3). Accordingly, there is provided a back termination corresponding to the Ron of two switches and the capacitor C1.

Because the differential driver 21 provides back termination with the capacitor C1 and the Ron of two switches, back terminating resistors may not be needed, which comparatively reduces the load on the output of the differential driver 21. As such, a differential driver having improved energy efficiency may be provided.

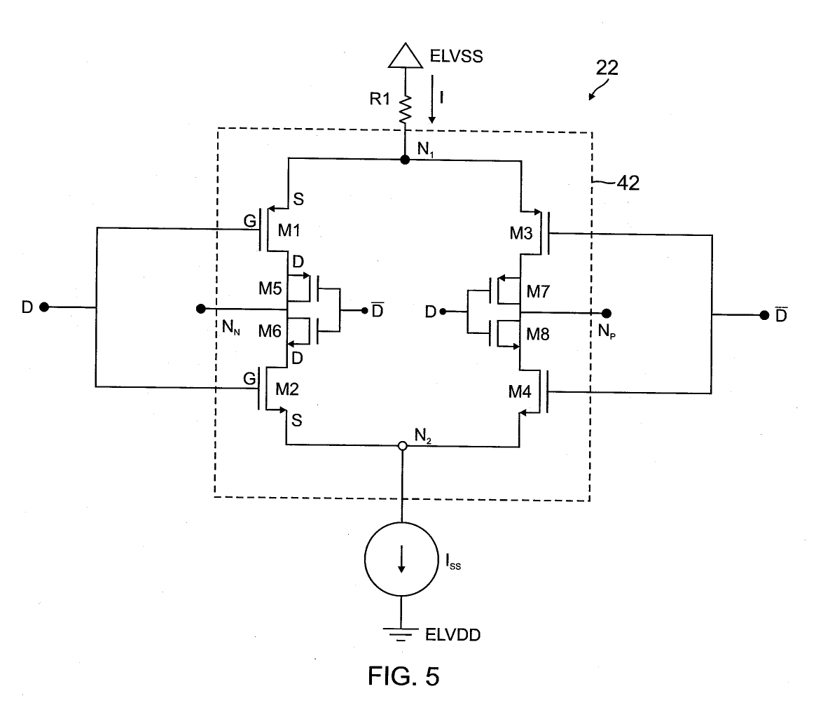

Referring now to FIG. 5, FIG. 5 is a schematic diagram of a low power LVDS driver having an AC glitch suppressor circuit according to another embodiment of the present invention. Since the low power LVDS driver according to the present embodiment may include substantially similar elements as those previously described, descriptions of certain aspects of the present embodiment are given by way of reference to the above descriptions and will not be described in detail herein.

A differential driver 22 according to another embodiment of the present invention includes a first power source ELVSS, an offsetting resistor R1, a constant current sink Iss, a second power source ELVDD, and a current steering circuit 42.

The current steering circuit 42 may include a first switch M1, a second switch M2, a third switch M3, and a fourth switch M4 to selectively steer a constant current I. These switches may be transistors, for example, MOSFETs. Each of the switches (M1-M4) may have its gate coupled to one of a data line D or an inverse data line D̅ to receive the data signal or the inverse data signal, respectively. Additionally, these switches may have their source or drain coupled to a positive differential output node Np or a negative differential output node Nn.

Each of these switches may include a characteristic capacitance between the gate and drain and/or the gate and source. As an example, the first transistor M1 may have a gate to drain capacitance Cgd. When the data signal switches logic states (e.g., 0 to 1), it may cause a disturbance of the drain of M1 due to the capacitance Cgd. Because the drain is coupled to the negative differential output node Nn, this may result in a disturbance on the differential signal, i.e., an AC glitch. Accordingly, it may be desirable to compensate for this capacitive effect to inhibit the AC glitch.

According to an embodiment of the present invention, the current steering circuit 42 compensates for an AC glitch. The current steering circuit 42 is substantially similar to the current steering circuit 40 described above except it includes switches M5 through M8.

The current steering circuit 42 of FIG. 5 includes a fifth switch M5 and a sixth switch M6, each being interposed between the first switch M1 and the second switch M2, and a seventh switch M7 and an eighth switch M8, each being interposed between the third switch M3 and the fourth switch M4. The fifth switch M5 and the sixth switch M6 may form a complementary pair, and the seventh switch M7 and the eighth switch may form another complementary pair. For example, the fifth switch M5 and the seventh switch M7 may be PMOS transistors, and the sixth switch M6 and the eighth switch M8 may be NMOS transistors, where a gate of each of the fifth switch M5 and the sixth switch M6 may be coupled to the inverse data line D̅ to receive the inverse data signal, and a gate of each of the seventh switch M7 and the eighth switch M8 may be coupled to the data line D to receive the data signal. The switches M5 through M8 may be dummy transistors, and may be half the size of the switches M1 through M4. Furthermore, the sources and drains of each of the switches M5 through M8 may be shorted to one another. This configuration allows for suppression of an AC glitch.

Turning back to the example including M1, because the first switch M1 receives the data signal and the sixth switch M6 receives the inverse data signal, these switches receive data signals which are exactly opposite in phase. So, when the logic state changes, while a charge is injected by the coupling capacitance Cgd of the first switch M1, an equal and opposite charge is removed by the coupling capacitance Cgd of the sixth switch M6. Thus switches M5 though M6 act like small coupling capacitors to couple into the signal to remove the charge this is being injected by the bit transition.

While embodiments of the low power LVDS communication network according to the present invention have been illustrated and described in connection with certain exemplary embodiments, it is to be understood that the invention is not limited to the described embodiments, but, on the contrary, is intended to cover various modifications and equivalent arrangements included within the spirit and scope of the appended claims. For example, while the exemplary embodiments of the present invention are described in connection with a low power LVDS communication network in a point-to-point configuration, embodiments of the communication network according to the present invention may also be in a multidrop configuration or a bi-direction half-duplex configuration.

What is claimed is:

1. A differential driver for transmitting a differential signal comprising:
a first power source configured to supply a first voltage;
a second power source configured to supply a second voltage that is less than the first voltage;
a current steering circuit coupled between the first power source and the second power source, the current steering circuit being configured to steer a current into either a positive differential output node or a negative differential output node to transmit the differential signal according to a data signal and a dataN signal;
a resistor interposed between the first power source and the current steering circuit; and
a constant current sink interposed between the current steering circuit and the second power source, the constant current sink being configured to sink the current having a substantially constant value,
wherein the dataN signal is the inverse of the data signal.

2. The differential driver of claim 1, wherein the current steering circuit is configured to receive the current having a voltage that is less than the first voltage by a voltage drop across the resistor.

3. The differential driver of claim 1,
wherein the current steering circuit comprises a bridged switch driver.

4. The differential driver of claim 1,
wherein the current steering circuit is configured to steer the current to flow from the positive differential output node through a terminating resistor to the negative differential output node when the data signal is high, and
wherein the current steering circuit is configured to steer the current to flow from the negative differential output node through the terminating resistor to the positive differential output node when the data signal is low.

5. The differential driver of claim 1,
wherein the current steering circuit comprises:
a current input node coupled to the first power source through the resistor;
a current output node coupled to the constant current sink;
a first switch coupled between the current input node and the negative differential output node;
a second switch coupled between the negative differential output node and the current output node;
a third switch coupled between the current input node and the positive differential output node; and
a fourth switch coupled between the current input node and the positive differential output node.

6. The differential driver of claim 5,
wherein the first switch and the third switch comprise p-type transistors, and
wherein the second switch and the fourth switch comprise n-type transistors.

7. The differential driver of claim 5,
wherein the first switch and the fourth switch are configured to turn on when the data signal is low, and
wherein the second switch and the third switch are configured to turn on when the data signal is high.

8. The differential driver of claim 7,
wherein the first switch comprises:
an input terminal coupled to the current input node;
an output terminal coupled to the negative differential output node; and
a gate configured to receive the data signal,
wherein the second switch comprises:
an input terminal coupled to the negative differential output node;
an output terminal coupled to the current output node; and
a gate configured to receive the data signal,
wherein the third switch comprises:
an input terminal coupled to the current input node;
an output terminal coupled to the positive differential output node; and
a gate configured to receive the dataN signal, and
wherein the fourth switch comprises:
an input terminal coupled to the positive differential output node;
an output terminal coupled to the current output node; and
a gate configured to receive the dataN signal.

9. The differential driver of claim 5,
wherein the current steering circuit further comprises a back termination circuit.

10. The differential driver of claim 9,
wherein the back termination circuit comprises a capacitor coupled between the current input node and the current output node.

11. The differential driver of claim 5,
wherein the current steering circuit further comprises an AC glitch suppressor, which comprises:
a fifth switch interposed between the negative differential output node and the second switch, the fifth switch comprising:
an input terminal coupled to the negative differential output node;
an output terminal coupled to the input terminal; and
a gate configured to receive the dataN signal;
a sixth switch interposed between the fifth switch and the second switch, the sixth switch comprising:
an input terminal coupled to the output terminal of the fifth switch;
an output terminal coupled to the input terminal and coupled to an input terminal of the second switch; and
a gate configured to receive the dataN signal; and
a seventh switch interposed between the positive differential output node and the fourth switch, the seventh switch comprising:
an input terminal coupled to the positive differential output node;
an output terminal coupled to the input terminal; and
a gate configured to receive the data signal; and
an eighth switch interposed between the seventh switch and the fourth switch, the eighth switch comprising:
an input terminal coupled to the output terminal of the seventh switch;
an output terminal coupled to the input terminal and coupled to an input terminal of the fourth switch; and
a gate configured to receive the data signal,
wherein the second switch, the third switch, the fifth switch, and the eighth switch are configured to turn on when the data signal is high, and
wherein the first switch, the fourth switch, the sixth, and the seventh switch are configured to turn on when the data signal is low.

12. A differential communication circuit comprising:
a differential receiver comprising:
a positive input terminal;
a negative input terminal;
a positive transmission line coupled to the positive input terminal of the differential receiver;
a negative transmission line coupled to the negative input terminal of the differential receiver;
a terminating resistor coupled between the positive transmission line and the negative transmission line; and
a differential transmitter comprising:
a first power source configured to supply a first voltage;
a second power source configured to supply a second voltage that is less than the first voltage;
a current steering circuit coupled between the first power source and the second power source, the current steering circuit being configured to steer a current into either a positive differential output node or a negative differential output node to transmit a differential signal according to a data signal and a dataN signal;
a resistor interposed between the first power source and the current steering circuit; and
a constant current sink interposed between the current steering circuit and the second power source, the constant current sink being configured to sink the current having a substantially constant value,
wherein the dataN signal is the inverse of the data signal,
wherein the positive differential output node is coupled to the positive transmission line, and
wherein the negative differential output node is coupled to the negative transmission line.

13. The differential communication circuit of claim 12,
wherein the current steering circuit is configured to receive the current having a voltage less than the first voltage by a voltage drop across the resistor.

14. The differential communication circuit of claim 12,
wherein the current steering circuit comprises a bridged switch driver.

15. The differential communication circuit of claim 12,
wherein the current steering circuit is configured to steer the current to flow from the positive differential output node through the terminating resistor to the negative differential output node when the data signal is high, and
wherein the current steering circuit is configured to steer the current to flow from the negative differential output node through the terminating resistor to the positive differential output node when the data signal is low.

16. The differential communication circuit of claim 12,
wherein the current steering circuit comprises:
a current input node coupled to the first power source through the resistor;
a current output node coupled to the constant current sink;
a first switch coupled between the current input node and the negative differential output node;
a second switch coupled between the negative differential output node and the current output node;
a third switch coupled between the current input node and the positive differential output node; and
a fourth switch coupled between the current input node and the positive differential output node.

17. A method of driving a differential signal, the method comprising:
providing a constant current at a first voltage;
shifting the first voltage to a second voltage; and
selectively steering the constant current at the second voltage to flow either from a positive differential node, through a terminating resistor, to a negative differential node, or from the negative differential node through the terminating resistor, to the positive differential node, according to a data signal to transmit the differential signal.

18. The method of claim 17,
wherein shifting the first voltage to the second voltage comprises supplying the constant current at the first voltage to an offsetting resistor before selectively steering the constant current.
